(19) United States
(12) Patent Application Publication
(10) Pub. No.: US 2007/0086206 A1
(43) Pub. Date: Apr. 19, 2007

(54) Light guiding structure for optical fiber

(76) Inventor: Allen Weng, Lujhu Township (TW)

Correspondence Address: HDSL, 4331 STEVENS BATTLE LANE, FAIRFAX, VA, 22033, US

(21) Appl. No.: 11/249,418

(22) Filed: Oct. 14, 2005

(51) Int. Cl. H01L 33/00

(52) U.S. Cl. 362/555

(57) ABSTRACT

A light guiding structure for optical fiber includes a stage, a plurality of light-guiding pipes and a base. The stage is defined with a plurality of through holes defined through upper face and lower face of the stage. The plurality of light-guiding pipes are arranged atop the plurality of through holes and each contains a plurality of optical fibers. A plurality of light emitting elements is arranged on the base and is received in the plurality of through holes when the stage is assembled with the base. Each of the light emitting elements is aligned with one light-guiding pipe. The light emitting elements can be controlled by external circuit for emitting light of multiple colors and the light is guided to remote place by the optical fibers to produce colorful visual effect.

### BACKGROUND OF THE INVENTION

1. Field of the Invention

The present invention relates to a light guiding structure, especially to a light guiding structure for optical fiber.

2. Description of Prior Art

The colorful lightings are generally used for visual attraction for people such as light board in department store or some festival places. The ordinary ways for colorful lightings use a single-color light bulb with transparent plates of different colors. The transparent plates of different colors are arranged to specific pattern and the light bulbs are driven in suitable timing to create pleasant visual effect.

However, the light bulb has the drawback of heat generation and will generate more heat in serial connection mode. The transparent plates may be deteriorated by the heat to change color thereof and the decoration lighted by the light bulb may also be deteriorated. Moreover, the exposed light bulb has the problem of short circuit. To solve above-mentioned problem, optical fibers are used to guide light from the light bulb and the optical fibers are enclosed with opaque envelope. Light emitted from ends of the optical fibers illuminates article or decoration without overeat or short-circuit problem.

However, the use of optical fiber for light transmission cannot provide changeable color. The color of emitted light is changed by the transparent plates of different colors. However, this arrangement will increase cost. Therefore, a motor is used to rotate the transparent plates of different colors and mono-color light bulb is used for light source. However, the size of above arrangement is bulky due to more components. The gap between the transparent plates of different colors will cause delay in color conversion and the flashing effect of color cannot be provided.

Light emitting diodes (LEDs) become popular replacement for light bulbs due to compact size, low thermal emission and capability for multiple colors. However, for larger size light board, very large amount of LED are needed to create desired pattern because the LED has compact size and small-area light spot. Therefore, complicated driving circuits are needed and the dynamic effect for visual color is influenced.

### SUMMARY OF THE INVENTION

According to one aspect of the present invention, the present invention provides a light guiding structure for assembling a plurality of light emitting elements. A plurality of through holes and a plurality of light-guiding pipes are provided to guide the light from optical fiber in colorful manner. The light guided to the optical fiber can be controlled by external controller to achieve colorful visual effect.

According to another aspect of the present invention, the present invention provides a light guiding structure with flexible shape.

According to still another aspect of the present invention, the present invention provides a light guiding structure with compact size.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows an exploded view of the present invention.

FIG. 2 shows the perspective view of the present invention.

FIG. 3 shows a sectional view of a preferred embodiment of the present invention.

FIG. 4 shows a sectional view of another preferred embodiment of the present invention.

FIG. 5 shows the rounded light guiding structure of the present invention.

FIG. 6 shows the rectangular light guiding structure of the present invention.

### DETAILED DESCRIPTION OF THE INVENTION

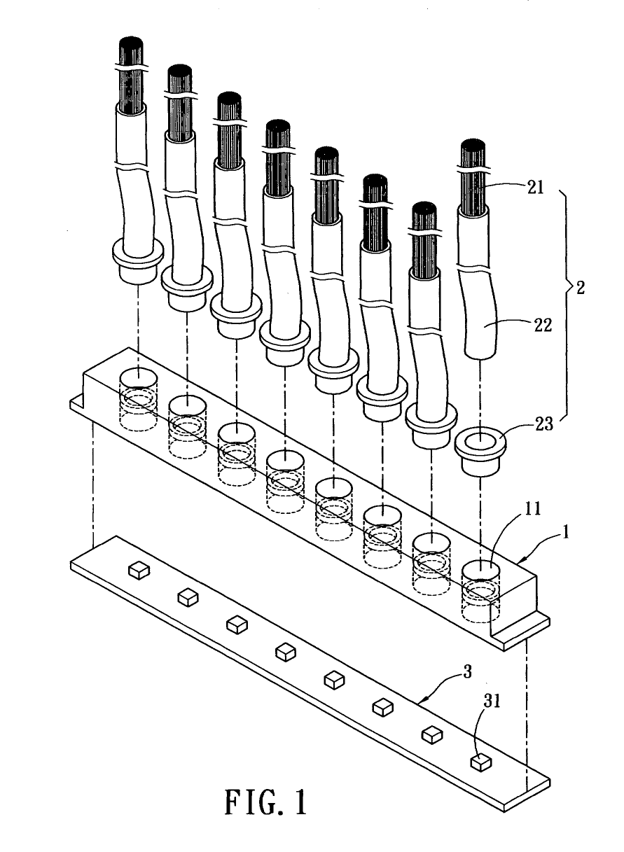

FIG. 1 shows an exploded view of the present invention. The light guiding structure according to the present invention comprises an elongated stage 1 made of opaque material and having a plurality of through holes 11 through two end faces of the stage 1, and a plurality of light-guiding pipes 2 arranged atop the through holes 11. Each of the light-guiding pipes 2 comprises a plurality of optical fibers 21 for guiding light and an opaque sleeve 22 to enclose the optical fibers 21. A connector 23 is connected to one end of the light-guiding pipe 2 and is pluggable to the through hole 11. A base 3 is arranged below the stage 1 and comprises a printed circuit board with area substantially the same as that of lower face of the stage 1. A plurality of light emitting elements are arranged on the base 3. In this preferred embodiment, the light emitting elements are LEDs 31 with positions corresponding to that of the through holes 11.

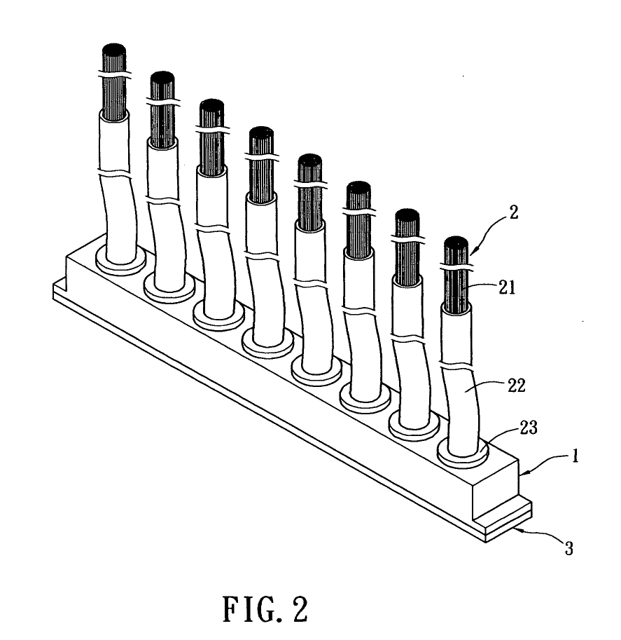

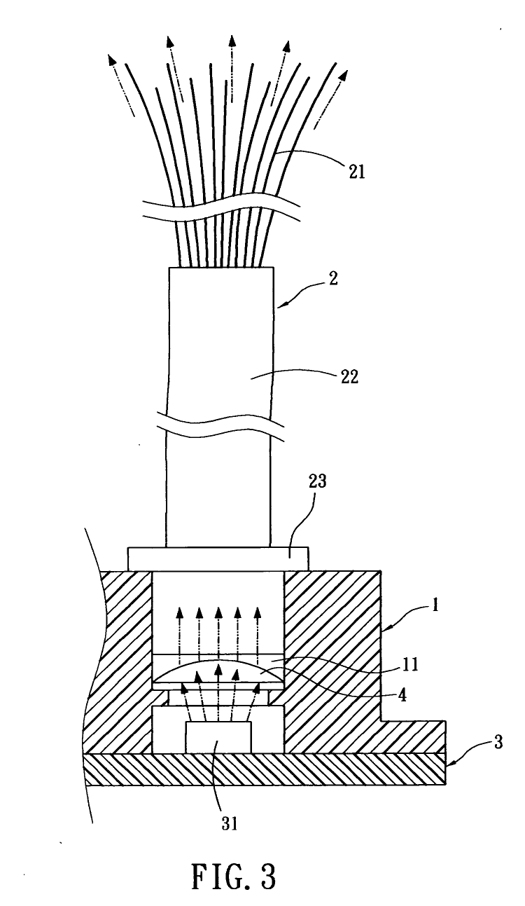

FIG. 2 shows the perspective view of the present invention. The light-guiding pipes 2 are mounted on the through holes 11 with the help of the connector 23. The base 3 is assembled to the lower face of the stage 1 and the LEDs 31 (not shown) on the base 3 are accommodated in the through holes 11. With reference to FIG. 3, when the connector 23 and the LEDs 31 are accommodated in the through holes 11, the plurality of fibers in the connector 23 are aligned with the LED 31. The light emitted from the LED 31 is guided to a remote end through the optical fibers 21 for illumination. Moreover, a focusing lens 4 is provided between the LED 31 and the optical fibers 21 for further guiding the light emitted from the LED 31 to the optical fibers 21. Therefore, the light emitted from the LED 31 can be guided to the remote end with more efficiency.

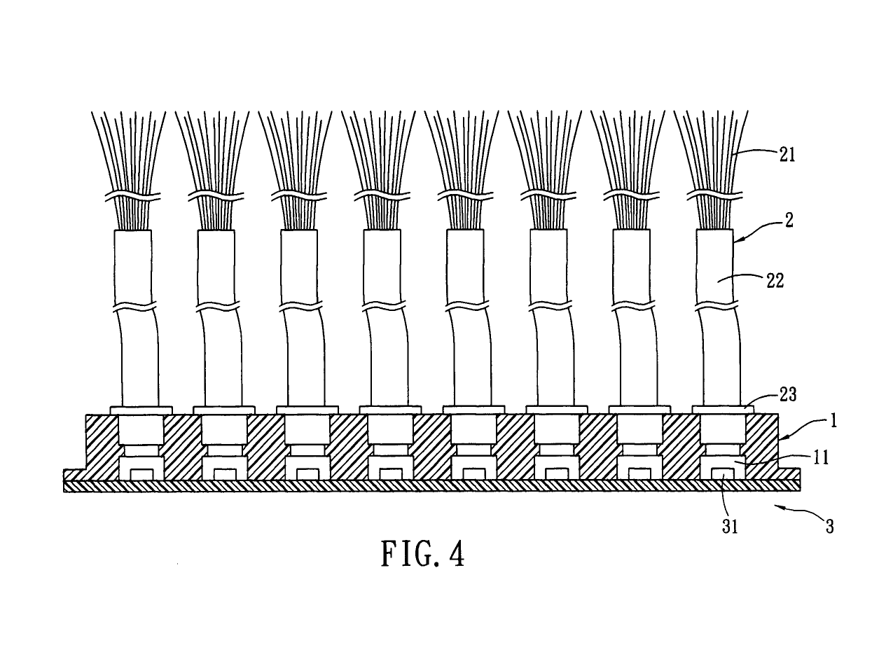

FIG. 4 shows a sectional view of another preferred embodiment of the present invention, wherein LED 31 of different colors are arranged on the base 3 and accommodated in the through holes 11. The timing of the LED 31 of different colors can be controlled through external controller to emit flashing light of different colors. The light of different colors are guided through respective optical fibers 21 to produce light spots of different colors. The light spots can be arranged to predetermined pattern by arranging the optical fibers 21.

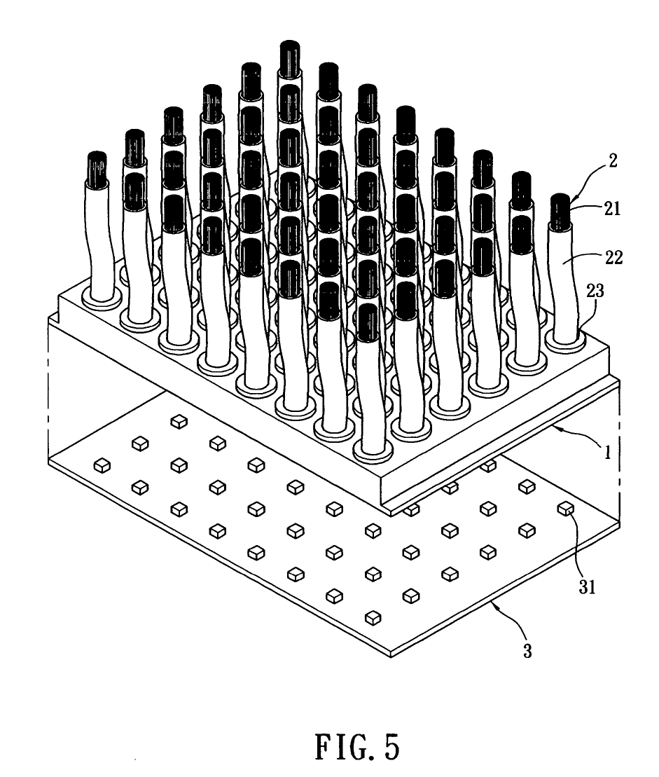

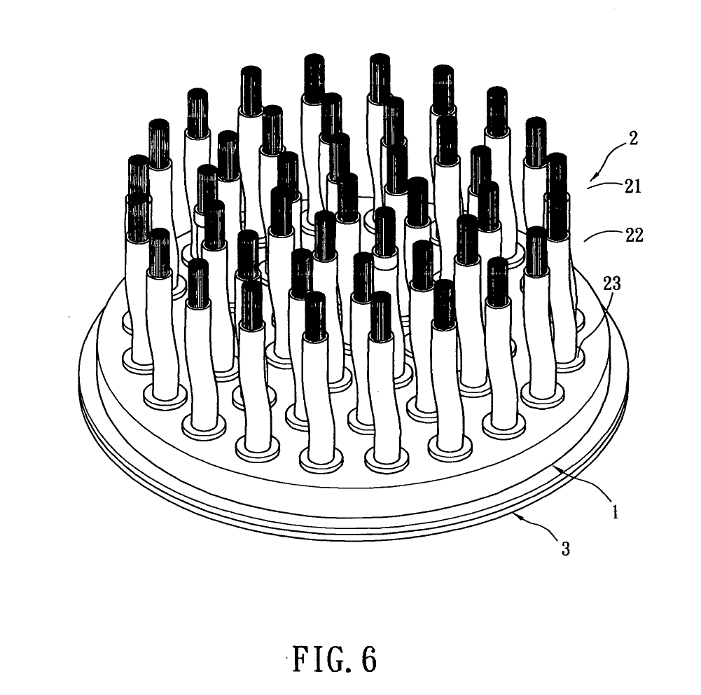

With reference to FIGS. 5 and 6, the stage 1 can be various shapes according to the present invention for different situations. Moreover, the pattern of the through holes 11 on the stage 1 can be varied according to practical situation. For example, the through holes 11 on the stage 1 can be arranged as array type. Similarly, LED of different colors are arranged in the through holes to produce desired and colorful visual effect.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A light guiding structure, comprising
a stage with a plurality of through holes defined on upper face and lower face of the stage;
a base assembled below the stage;
a plurality of light emitting elements arranged on the base;
a plurality of light-guiding pipes comprising a plurality of optical fibers for guiding light;
wherein the plurality of light-guiding pipes and the plurality of light emitting elements are accommodated in the through holes such that each of the light emitting elements is corresponding to one of the light-guiding pipes and light emitted by the light emitting elements is guided to a remote site by the light-guiding pipe.

2. The light guiding structure as in claim 1, wherein the stage is made of opaque material.

3. The light guiding structure as in claim 1, wherein the through holes are defined through the upper face and the lower face of the stage.

4. The light guiding structure as in claim 1, wherein the through holes are defined in array fashion.

5. The light guiding structure as in claim 1, wherein the base is a printed circuit board.

6. The light guiding structure as in claim 1, further comprising a focusing lens placed between the light emitting elements and the light-guiding pipes.

7. The light guiding structure as in claim 1, wherein the light emitting element is light emitting diode.

8. The light guiding structure as in claim 1, wherein the light emitting element emit mono-color light.

9. The light guiding structure as in claim 1, wherein the light emitting element emit multiple-color light.

10. The light guiding structure as in claim 1, wherein the light-guiding pipe further comprises a connector and a sleeve.

11. The light guiding structure as in claim 10, wherein the connector is integral with the sleeve.

12. The light guiding structure as in claim 10, wherein the connector is connected with the sleeve.
